(19) United States
(12) Patent Application Publication
(10) Pub. No.: US 2015/0318149 A1
(43) Pub. Date: Nov. 5, 2015

(54) SYSTEMS AND METHODS FOR GENERATING HIGH PRESSURE DISCHARGE

(71) Applicant: Krupakar Murali Subramanian, Komarapalayam (IN)

(72) Inventor: Krupakar Murali Subramanian, Komarapalayam (IN)

(21) Appl. No.: 14/651,549

(22) PCT Filed: Dec. 11, 2013
(86) PCT No.: PCT/IB2013/060792

§ 371 Date: Jun. 11, 2015

(30) Foreign Application Priority Data
Dec. 13, 2012 (IN) 5191/CHE/2012

(51) Int. Cl. H01J 37/32

(52) U.S. Cl. CPC H01J 37/32348; H01J 37/32532; H01J 2237/002

(57) ABSTRACT

Systems and methods for high pressure plasma discharge, wherein a system comprises
at least one electrode which is fragmented into pieces and arranged to form a fragmented electrode system;
at least one dielectric material placed between or parallel to the at least one electrode and another second electrode or fragmented pieces of the fragmented electrode systems, wherein the at least one electrode or fragmented pieces of the fragmented electrode system may have same or opposite charge; and
at least one power supply unit;
wherein the pieces of the electrode which is fragmented can be arranged parallel or divergent or convergent to one another and are at an angle to each other or the central axis passing through the electrode.

### FIELD OF INVENTION

The present invention relates to Dielectric-barrier discharge (DBDs) and more specifically relates to systems and methods for high pressure plasma discharge typically used for wide surface area treatment.

The invention is particularly useful for the surface treatment of a fabric

The invention is particularly useful for generation of reactive gases.

### BACKGROUND OF THE INVENTION

Dielectric-barrier discharge (DBDs) is the electrical discharge between two electrodes separated by an insulating dielectric barrier, also referred to as barrier discharges or silent discharges.

The conventional systems for dielectric barrier discharge have been used in number of applications such as but not limited to generation of optical radiation, generation of plasma, water treatment, textile treatment, sterilization, deposition, etching, etc. Dielectric barrier discharge (DBD) systems can operate at, below, or even above atmospheric pressure.

As noted above, it has been demonstrated that application of homogeneous diffuse discharges can also be obtained in DBD configurations even at atmospheric pressure. For Ex. K. Donohoe (PhD Thesis, California Institute of Technology, Pasadena, Calif. (1976)) obtained a uniform glow discharge with pulsed excitation in a helium/ethylene mixture.

The term APG, standing for atmospheric pressure glow was proposed by S. Okazaki et. al, (S. Kanazawa, M. Kogoma, T. Moriwaki, S. Okazaki, 8th International Symposium on Plasma Chemistry, Tokyo (1987) 1839-1844; S. Kanazawa, M. Kogoma, T. Moriwaki, S. Okazaki, J. Phys. D: Appl. Phys. 21 (1988) 838-840; S. Okazaki, M. Kogoma, M. Uehara, Y. Kimura, J. Phys. D: Appl. Phys. 26 (1993) 889-892) to generate uniform glow discharges at atmospheric pressure in helium, air, argon, oxygen and nitrogen even when using a 50 Hz power source they used an electrode configuration consisting of two metal foils covered with a special metal mesh and ceramic plates. More detailed investigations followed by F. Massines (F. Massines, C. Mayoux, R. Messaoudi, A. Rabehi, P. Ségur, Int. Conf. on Gas Discharges and their Applications, Swansea, UK (1992) 730-733; F. Massines, A. Rabehi, P. Decomps, R. B. Gadri, P. Ségur, C. Mayoux, J. Appl. Phys. 83 (1998) 2950-2957) and her group at Toulouse. Apparently independently of these investigations, a group around J. R. Roth (J. R. Roth, P. P. Tsai, L. C. Wadsworth, U.S. Pat. No. 5,403,453 of Apr. 4, 1995) at the University of Tennessee at Knoxville re-invented what they called an OAUGDP (one atmosphere uniform glow discharge plasma) and even obtained a US patent for a “Method and apparatus for glow discharge plasma treatment of polymer materials at atmospheric pressure”. Glow discharges in atmospheric pressure gases were already mentioned by von Engel, Seeliger and Steenbeck in 1933, and by Gambling and Edels in 1956.

Necessary requirements of a minimum initial electron density were formulated and described by Palmer (A. J. Palmer, Appl. Phys. Lett. 25 (1974) 138-140) and by Levatter and Lin (J. I. Levatter, S. Lin, J. Appl. Phys. 51 (1980) 210-222).

More recently Brenning et al. (N. Brenning, I. Axnäs, J. O. Nilsson, J. E. Eninger, IEEE Trans. Plama Sci. 25 (1997) 83-88) formulated more detailed conditions for obtaining homogenous high-pressure pulsed avalanche discharges. They point out the importance of an additional minimum pre-ionization rate just prior to and during breakdown.

The most important quantity is the effective primary ionization coefficient Ieff (including all attachment and detachment processes) at the moment of breakdown or, more precisely, its derivative with respect to the reduced field: d(Ieff/n)/d(E/n). This quantity is strongly affected by impurities, gas additives and the presence of metastables and residual ions. Tepper et al., (J. Tepper, M. Lindmayer, J. Salge, HAKONE VI, Cork, Ireland (1998) 123-127) demonstrated, dielectrics are capable of accumulating appreciable amounts of charges on the surface. Supported by the applied voltage the charges are trapped uniformly on the surface. When the electric field changes its polarity and exceeds a certain threshold value, the charge carriers are expelled spontaneously from the surface and initiate a homogeneous discharge.

However, due to the configuration as described in conventional systems have various drawbacks such as it is unreliable in controlling homogeneous glow discharges at atmospheric pressure. For instance, changes of the electrode configuration or small variations of the amplitude or repetition frequency of the applied voltage can cause a transition into a more stable filamentary discharge mode. For industrial applications this could be a severe drawback compared to filamentary discharges. This problem is compounded when large electrodes are used. Such large electrodes could warp and the power supply used would also be large and cumbersome. Fine adjustment of spacing between the electrodes is relatively difficult or sometimes impossible.

Use of Dielectric-barrier discharge (DBDs) in the surface treatment of fabric is known in the art. The aim of the plasma surface treatment of fabric is to improve surface properties of fabric such as wettability, colourability, adhesion to other material, sterilization and many other applications. Fabrics are made up of organic or inorganic fibers; the surface of the fabric can be modified by variety of the methods. The systems and methods in the prior art lack homogeneity in the plasma surface treatment due to the various drawbacks associated with such as electrode size, electrode shape, electrode arrangement, position of dielectric, thickness of dielectric with respect to the electrode system, use of gas, applied electrode voltage leads to non uniform generation of plasma.

Hence, there is a requirement of systems which may reduce or overcome one or more of the abovementioned problems and drawbacks.

### OBJECTS OF THE INVENTION

An object of the invention is to provide systems and methods for generation of high pressure plasma discharge which contains at least one electrode which is fragmented into pieces, wherein a set of the fragmented pieces form a fragmented electrode system.

Another object of the invention is to provide systems and methods for generation of high pressure plasma discharge for uniform plasma generation over a wide area.

Yet another object of the invention is to provide systems and methods for generation of high pressure plasma discharge, wherein system comprises at least two electrodes which have a concentric arrangement with respect to one another, wherein the at least two electrodes form a contraption between the inner and the outer electrode.

Still another object of the invention is to provide systems and methods for generation of high pressure plasma discharge for treatment of inner and outer surface for woven and non woven fabrics or cords from organic and inorganic fibers with the aim to change surface properties of the fibers.

### SUMMARY OF THE INVENTION

In one aspect, the present invention involves systems and methods for high pressure plasma discharge, wherein a system comprises

at least one electrode which is fragmented into pieces and arranged to form a fragmented electrode system; and
at least one dielectric material placed between or parallel to the at least one electrode and another second electrode or fragmented pieces of the fragmented electrode systems;
wherein the at least one electrode and another second electrode or fragmented pieces of the fragmented electrode system may have same or opposite charge;
wherein the pieces of the electrode which is fragmented can be arranged parallel or divergent or convergent to one another and are at an angle to each other or the central axis passing through the electrode

In another aspect, the present invention involves systems and methods for high pressure plasma discharge, wherein a system comprises

at least two electrodes which have a concentric arrangement with respect to one another, wherein the at least two electrodes form a contraption between the inner and the outer electrode; and
at least one dielectric material placed between or parallel to the at least one electrode and another second electrode or fragmented pieces of the fragmented electrode systems, wherein the said electrodes or fragmented electrode systems may have same or opposite charge;
wherein the inner or outer surface of at least one of the electrodes tapers in at least one direction

### BRIEF DESCRIPTION OF THE ACCOMPANYING DRAWINGS

FIG. 1 is an exemplary embodiment illustrating the isometric view of the at least one electrode which is fragmented into pieces and arranged to form a fragmented electrode system

FIG. 2 is an exemplary embodiment illustrating the isometric view of a fragmented electrode system wherein the fragmented pieces are hollow or partially filled parallelepiped

FIG. 3 is an exemplary embodiment illustrating the isometric view of a fragmented electrode system wherein the fragmented pieces are placed parallel with respect to one another and perpendicular to the central axis passing through the fragmented electrode system;

FIG. 4a and FIG. 4b are exemplary embodiments illustrating the fragmented electrode system wherein the fragmented pieces (401a and 401b) are placed parallel with respect to one another are at an angle (θ) to the central axis passing through the fragmented electrode system;

FIG. 5a, FIG. 5b, and FIG. 5c are exemplary embodiments illustrating the isometric view of a pair of electrodes, wherein the views illustrate the various positions of at least one electrode with respect to another second electrode.

FIG. 6a, FIG. 6b, FIG. 6c, and FIG. 6d are exemplary embodiments illustrating the arrangement of the fragmented pieces with respect to one another in a fragmented electrode system;

FIG. 7 is an exemplary embodiment illustrating perforations on the fragmented pieces of a fragmented electrode system;

FIG. 8a and FIG. 8b are side and top views, respectively, of an exemplary embodiment illustrating tubular fragmented pieces of a fragmented electrode system;

FIG. 9a and FIG. 9b are isometric views of exemplary embodiments illustrating the various configurations of the at least one electrode and the another second electrode or the fragmented pieces of the fragmented electrode system with respect to one another and with respect to the at least one dielectric material;

FIG. 10 is the isometric views of an exemplary embodiment illustrating the another configuration for application of different or varied frequencies to the at least one electrode and the another second electrode or the fragmented pieces of the fragmented electrode system;

FIG. 11, FIG. 12a, FIG. 12b, FIG. 12c, FIG. 13a, FIG. 13b, and FIG. 13c illustrates various views of embodiments of systems for high pressure plasma discharge comprising at least two electrodes having a concentric arrangement with respect to one another, wherein the at least two electrodes form a contraption between the inner and the outer electrode; and wherein at least a portion of the inner or outer surface of at least one of the at least two electrodes tapers in at least one direction;

FIG. 14a, FIG. 14b, FIG. 14c, and FIG. 14d illustrate various isometric views of an embodiment of the invention, wherein at least one dielectric material is placed between the at least two electrodes;

FIG. 15a and FIG. 15b illustrate various isometric views of exemplary embodiments illustrating the arrangement of an array of the at least two electrodes which have a concentric arrangement with respect to one another, wherein the two electrodes form a contraption between the inner and the outer electrode;

FIG. 16a, FIG. 16b, and FIG. 16c illustrate various isometric views of exemplary embodiments illustrating the arrangement of an array of fragmented pieces (7001) of a fragmented electrode system and at least one dielectric material (7004) placed parallel to the fragmented pieces of the fragmented electrode system;

FIG. 17 illustrate isometric views of ‘couplers’ to hold tubes of FIG. 16a, FIG. 16b, and FIG. 16c at any orientation;

FIG. 18a and FIG. 18b illustrate isometric views of exemplary embodiments illustrating the array such as that described FIG. 16a, FIG. 16b, and FIG. 16c enclosed in a containment chamber;

FIG. 19 illustrate an exemplary embodiment illustrating a fragmented electrode system is placed within a gas container containing a gas with lower molecular weight than the gas contained in another gas container containing a gas with higher molecular weight.

FIG. 20 illustrate an exemplary embodiment illustrating two fragmented electrode system is placed within two gas container containing gases with lower molecular weight than the gas contained in another gas container containing a gas with higher molecular weight.

### DETAILED DESCRIPTION OF THE ACCOMPANYING DRAWINGS

In one aspect, the present invention involves systems and methods for high pressure plasma discharge, wherein a system comprises.

at least one electrode which is fragmented into pieces and arranged to form a fragmented electrode system;
at least one dielectric material placed between or parallel to the at least one electrode and another second electrode or fragmented pieces of the fragmented electrode systems, wherein the at least one electrode or fragmented pieces of the fragmented electrode system may have same or opposite charge; and
at least one power supply unit;
wherein the pieces of the electrode which is fragmented can be arranged parallel or divergent or convergent to one another and are at an angle to each other or the central axis passing through the electrode.

In one aspect, the present invention involves systems and methods for high pressure plasma discharge, wherein a system comprises.

at least one electrode which is fragmented into pieces and arranged to form a fragmented electrode system; and
at least one dielectric material placed between or parallel to the at least one electrode and another second electrode or fragmented pieces of the fragmented electrode systems;
wherein the at least one electrode and another second electrode or fragmented pieces of the fragmented electrode system may have same or opposite charge;
wherein the pieces of the electrode which is fragmented can be arranged parallel or divergent or convergent to one another and are at an angle to each other or the central axis passing through the electrode

In one aspect, the present invention involves systems and methods for high pressure plasma discharge, method comprising the steps of,

arranging fragmented pieces of at least one electrode to form a fragmented electrode system;
placing at least one dielectric material between or parallel to the at least one electrode and another second electrode or fragmented pieces of the fragmented electrode systems;
charging the at least one electrode and another second electrode or the fragmented pieces of the fragmented electrode system with same or opposite charge using at least one power supply unit;
passing a process gas through the at least one electrode and another second electrode or the fragmented pieces of the fragmented electrode system having same or opposite charge;
placing a processing material between the at least one electrode and another second electrode or the fragmented pieces of the fragmented electrode system having same or opposite charge; and
treating a processing material placed between the at least one electrode and another second electrode or the fragmented pieces of the fragmented electrode system having same or opposite charge;
wherein the pieces of the electrode which is fragmented is arranged parallel or divergent or convergent to one another and are at an angle to each other or the central axis passing through the electrode

In one aspect, the present invention involves systems and methods for high pressure plasma discharge, method comprising the steps of,

arranging fragmented pieces of at least one electrode to form a fragmented electrode system;
placing at least one dielectric material between or parallel to the at least one electrode and another second electrode or fragmented pieces of the fragmented electrode systems;
charging the at least one electrode and another second electrode or the fragmented pieces of the fragmented electrode system with same or opposite charge;
passing a process gas through the at least one electrode and another second electrode or the fragmented pieces of the fragmented electrode system having same or opposite charge;
placing a processing material between the at least one electrode and another second electrode or the fragmented pieces of the fragmented electrode system having same or opposite charge; and
treating a processing material placed between the at least one electrode and another second electrode or the fragmented pieces of the fragmented electrode system having same or opposite charge;
wherein the pieces of the electrode which is fragmented is arranged parallel or divergent or convergent to one another and are at an angle to each other or the central axis passing through the electrode.

In another aspect, the present invention involves systems and methods for high pressure plasma discharge, wherein a system comprises

at least two electrodes which have a concentric arrangement with respect to one another, wherein the two electrodes form a contraption between the inner and the outer electrode;
at least one dielectric material placed between or parallel to the at least one electrode and another second electrode or fragmented pieces of the fragmented electrode systems, wherein the said electrodes or fragmented electrode systems may have same or opposite charge; and
at least one power supply unit;
wherein the inner or outer surface of at least one of the electrodes tapers in at least one direction

In another aspect, the present invention involves systems and methods for high pressure plasma discharge, wherein a system comprises.

at least two electrodes which have a concentric arrangement with respect to one another, wherein the at least two electrodes form a contraption between the inner and the outer electrode; and
at least one dielectric material placed between or parallel to the at least one electrode and another second electrode or fragmented pieces of the fragmented electrode systems, wherein the said electrodes or fragmented electrode systems may have same or opposite charge;
wherein the inner or outer surface of at least one of the electrodes tapers in at least one direction

In one aspect, the present invention involves systems and methods for high pressure plasma discharge, method comprising the steps of,

arranging at least two electrodes in a concentric arrangement with respect to one another such that the at least two electrodes form a contraption between the inner and the outer electrode;
placing at least one dielectric material between or parallel to the at least one electrode and another second electrode or fragmented pieces of the fragmented electrode systems;
charging the at least one electrode and another second electrode or the fragmented pieces of the fragmented electrode system with same or opposite charge;
passing a process gas through the at least one electrode and another second electrode or the fragmented pieces of the fragmented electrode system having same or opposite charge using at least one power supply unit;
placing a processing material between the at least one electrode and another second electrode or the fragmented pieces of the fragmented electrode system having same or opposite charge; and
treating a processing material placed between the at least one electrode and another second electrode or the fragmented pieces of the fragmented electrode system having same or opposite charge;
wherein the inner or outer surface of at least one of the electrodes tapers in at least one direction.

In accordance with another embodiment of this invention, there is provided at least an anode part (214) and at least a cathode part (216). At least an anode part and at least a cathode part, typically, are wire loo In one aspect, the present invention involves systems and methods for high pressure plasma discharge, method comprising the steps of,

arranging at least two electrodes in a concentric arrangement with respect to one another such that the at least two electrodes form a contraption between the inner and the outer electrode;
placing at least one dielectric material between or parallel to the at least one electrode and another second electrode or fragmented pieces of the fragmented electrode systems;
charging the at least one electrode and another second electrode or the fragmented pieces of the fragmented electrode system with same or opposite charge;
passing a process gas through the at least one electrode and another second electrode or the fragmented pieces of the fragmented electrode system having same or opposite charge;
placing a processing material between the at least one electrode and another second electrode or the fragmented pieces of the fragmented electrode system having same or opposite charge; and
treating a processing material placed between the at least one electrode and another second electrode or the fragmented pieces of the fragmented electrode system having same or opposite charge;
wherein the inner or outer surface of at least one of the electrodes tapers in at least one direction.

In an embodiment of the invention, line drawn through one end of one of the pieces of the electrode which is fragmented coincides with the lower tip of the adjacent piece of the electrode.

In an embodiment of the invention, the another second electrode of system in accordance with the invention may optionally be a fragmented electrode system or an electrode which remains unfragmented.

In an embodiment of the invention, the fragmented pieces of the fragmented electrode system may be independently or simultaneously arranged parallel or divergent or convergent to one another or zig-zag and is at an angle between 0 and 360° to each other or the axis passing through the fragmented electrode system

In an embodiment of the invention, more than one electrode may be fragmented into pieces and arranged to form a fragmented electrode system.

In an embodiment of the invention, the at least one electrode or fragmented pieces of a fragmented electrode system in accordance with the invention may additionally or optionally of various shapes such as or similar to, but not limited to taper, curved, flat, tubular, circular, elliptical, rectangular, square, polygonal or any combination thereof.

In an embodiment of the invention, the at least one electrode or fragmented pieces of a fragmented electrode system in accordance with the invention may be arranged in same or multiple planes

In an embodiment of the invention, the at least one electrode or fragmented pieces of a fragmented electrode system in accordance with the invention may be oriented in same, opposite, or multiple directions.

In an embodiment of the invention, space or gap between the at least one electrode and the another second electrode or fragmented pieces of the fragmented electrode system may vary concurrently or independently.

In an embodiment of the invention, the number or dimensions of fragmented pieces of the fragmented electrode system is suitably varied according to its application and requirement

In an embodiment of the invention, electrodes or fragmented electrode systems may be stationary or could be mounted on a moving platform/robot

In an embodiment of the invention, at least one electrode or fragmented piece of a fragmented electrode system in accordance with the invention may contain one or more perforation(s) along the surface of the at least one electrode or fragmented piece of a fragmented electrode system

The term perforation(s) for the purpose of this invention shall include but is not limited to aperture, cavities, lacuna, hole, vent, or any combination thereof

Typically, process gas may be introduced through the perforation(s) along the surface of at least one electrode or fragmented piece of a fragmented electrode system contain.

Alternately, processed gas may be collected through the perforation(s) along the surface of at least one electrode or fragmented piece of a fragmented electrode system contain.

In an embodiment of the invention, one or more perforation may additionally or optionally be present along the surface of the at least one dielectric material

Typically, process gas may be introduced through the perforation(s) along the surface of the said dielectric material

Alternately, processed gas may be collected through the perforation(s) along the surface of the said dielectric material.

Typically, the process gas may also be introduced along with the substrate being processed and the flow of such gases is obtained by the surface drag of the substrate or through forced convection like a fan

In an embodiment of the invention, the process gas in accordance with the invention may be any suitable gas such as but not limited to air, organic gas, inorganic gas, helium, neon, argon, xenon, noble gases, suspended particles, droplets of fluids, or any combination thereof. These process gases may be used alone or in combination other gases.

In an embodiment of the invention, the at least one dielectric material may be placed equidistant from the at least one electrode and the another second electrode or the fragmented electrode system or closer to any of the at least one electrode or the another second electrode or the fragmented electrode system

In an embodiment of the invention, more than one dielectric material may be present in between the at least one electrode and the another second electrode or the fragmented electrode system.

In an embodiment of the invention, dielectric material may be in level with the surface of the at least one electrode and the another second electrode or the fragmented electrode system or may be protruding out

In an embodiment of the invention, the system in accordance with present invention may consist of more than the at least one dielectric material, wherein the dielectric material is optionally, simultaneously, or independently placed between the at least one electrode and another second electrode or the fragmented pieces of the fragmented electrode system, or around the at least one electrode and another second electrode or the fragmented pieces of the fragmented electrode system, or partially or completely covering the at least one electrode and another second electrode or the fragmented pieces of the fragmented electrode system or any combination thereof

In an embodiment of the invention, the at least one dielectric material in accordance with the invention may have various surface contours such as but not limited to smooth, regular, irregular, grained, wavy, serrated, wedged, teethed, or any combination thereof.

In an embodiment of the invention, the at least one dielectric material in accordance with the invention may be solid, or liquid or semisolid or gaseous dielectric material such as but is not limited to glass, quartz, ceramics, porcelain, plastics, air, nitrogen, sulfur hexafluoride, or any combination thereof

In an embodiment of the invention, the processing material may be used as the dielectric material

In an embodiment of the invention, the at least one electrode or the fragmented pieces of the fragmented electrode system has polygonal cross-sectional shape, wherein the polygon comprises ‘n’ sides, where may be defined as n=3 (corresponding to a triangle) to infinity (corresponding to a circle)

In an embodiment of the invention, the at least one electrode or the fragmented pieces of the fragmented electrode system may be flat or curved inwards or outwards

For the purpose of this invention, ‘process gas’ or ‘processed gas’ or ‘processing material’ or ‘processed material’ describes matter or object which is being treated by the systems and methods of the present invention

In an embodiment of the invention, the systems in accordance with the invention may be cooled by circulation of a cooling agent such as but not limited to air, water, nitrogen, hydrogen, freon, helium or the process gas, colloids, gels, colloidal suspensions, fluids or any combination thereof

In an embodiment of the invention, the at least one electrode or the fragmented pieces of the fragmented electrode system may be hollow or solid.

In an embodiment of the invention, the at least one electrode or the fragmented piece of a fragmented electrode system in accordance with the invention may be a solid structure or a hollow structure.

In an embodiment of the invention, the at least one hollow electrode or the hollow fragmented piece of a fragmented electrode system helps to dissipate excess heat.

In an embodiment of the invention, at least two electrodes may be stacked above one another. Reactive gases can be generated between such stacked plates and can be collected from any convenient opening. Such an opening can be easily designed by those skilled in the art.

In an embodiment of the invention, the at least one electrode or the fragmented piece of a fragmented electrode system may be tubular of varying length and varied cross-section.

In an embodiment of the invention, the inner surface of the outer electrode or the outer surface of the inner electrode or both concurrently or independently or simultaneously tapers in at least one direction.

In an embodiment of the invention, the dielectric material may completely or partially cover an electrode or a fragmented electrode system or a piece of the electrode which is fragmented

In an embodiment of the invention, the thickness of the said dielectric material may vary at various parts of the electrode or a fragmented electrode system

In an embodiment of the invention, the power supply unit may include but is not limited to capacitor or bulk capacitor, or bank of capacitors, battery(ies), gas excitation or application high voltage potential or by application of time varying voltage also known as AC (alternating current) voltage or RF (radio frequency) energy or any combination thereof.

The terms “electrode” or ‘fragmented electrode system’ for the purpose of this invention may include but is not limited to a cathode part, an anode part, or any combination thereof, wherein any of the electrode or fragmented electrode system may or may not be charged at an instant.

The term cathode part represents any part that is at relatively lower voltage compared to another electrode in the system

The term anode part represents any part that is at relatively higher voltage compared to another electrode in the system.

In an embodiment of the invention, the vents may optionally be present to prevent turbulent mixing between the two gases with vastly different molecular weights. These vents may be further connected to an external unit to separate the accumulated ‘processed gases’ over a period of time. Those skilled in the art can design and build such units.

Typically, flaps, optionally made of flexible or inflexible material such as but not limited to rubber, are placed to hold the fabric or a ‘processing material’ in place. These flaps prevent atmospheric gases from entering and mixing with the gases within the said gas containers or process gas from leaving the system.

In an embodiment of the invention, more than two gases may be used in the gas containers. Furthermore, more than one gas may also be used in a single container. Those skilled in the art can design such units.

In an embodiment of the invention, the system in accordance with the invention may produce plasma.

The term “plasma” is used to identify gaseous complexes which may comprise electrons, positive or negative ions, gaseous atoms and molecules in the ground state, radicals or any higher state of excitation including light quanta.

In an embodiment of the invention, the system in accordance with the present invention may be used in the various surface treatment processes such as but not limited to sterilization, cleaning, etching, coating, or any combination thereof

In an embodiment of the invention, the system in accordance with the invention may be used to process various processing materials.

In an embodiment of the invention, the system in accordance with the invention may be used to process fabrics made up of various types of fibers such as but not limited to natural fibers, synthetic fibers, inorganic fibers, or any combination thereof

In an embodiment of the invention, at least one electrode or fragmented pieces of fragmented electrode system or at least one dielectric material in accordance with the invention may additionally or optionally be equal or unequal in number; or aligned or unaligned.

FIG. 1 is an exemplary embodiment illustrating the isometric view of the at least one electrode which is fragmented into pieces (101) and arranged to form a fragmented electrode system. In this example the fragmented pieces (101) are arranged parallel to one another.

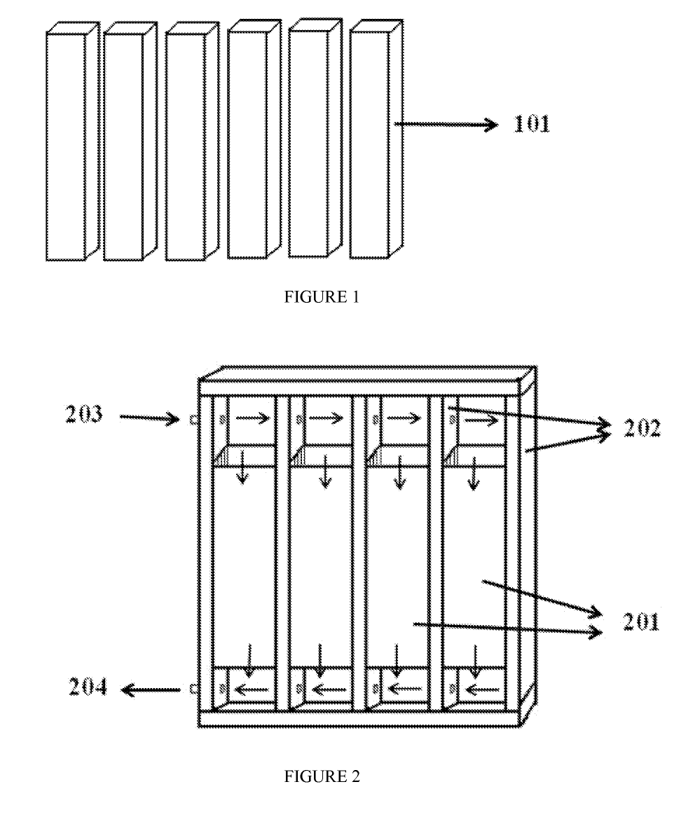

FIG. 2 is an exemplary embodiment illustrating the isometric view of a fragmented electrode system wherein the fragmented pieces are hollow parallelepipeds (201), wherein each of the hollow parallelepiped fragmented piece (201) is separated from the other by at least one dielectric material (202) placed between the hollow parallelepiped fragmented pieces (201). The at least one dielectric material (202) extend beyond the length of the hollow parallelepiped fragmented pieces (201). The system described in the instant embodiment may further be enclosed in an enclosure with inlet (203) for process gas to enter the system and circulate through the hollow parallelepiped fragmented pieces (201) and be expelled out through the outlet (204). The FIG. 2 also shows the direction of movement of the process gas within the system passing through openings present on the at least one dielectric material (202) with the help of arrowheads.

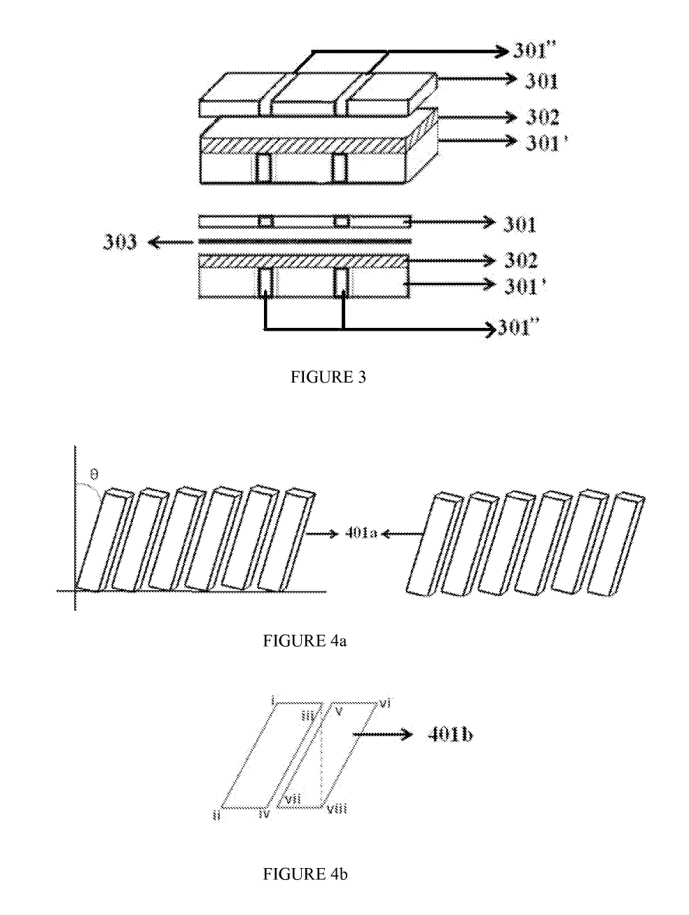

FIG. 3 is an exemplary embodiment illustrating the isometric view of a fragmented electrode system wherein the fragmented pieces are placed parallel with respect to one another and perpendicular to the central axis passing through the fragmented electrode system. The FIG. 3 has two parts, first part of which illustrates two fragmented electrode systems (301, 301′) and one of the fragmented electrode system (301′) is covered with the at least one dielectric material (302). The second part of the FIG. 3 illustrates the movement of the fabric (303) through the gap between the fragmented electrode system (301) and fragmented electrode system (301′) which is covered with the at least one dielectric material (302). In both the first part and second part of the FIG. 3 the instant embodiment of the invention illustrates gaps (301″) i. e. the regions just below the dielectric material in between the fragmented pieces of the fragmented electrode systems (301, 301′). A disadvantage associated with this arrangement are gaps (301″) i. e. the regions just below the dielectric material in between the fragmented pieces of the fragmented electrode systems (301, 301′) where there is no plasma formation. This would tend to leave seams on the processing material where the surface is inefficiently treated by plasma.

FIG. 4a and FIG. 4b are exemplary embodiments illustrating the fragmented electrode system wherein the fragmented pieces (401a and 401b) are placed parallel with respect to one another are at an angle (θ) to the central axis passing through the fragmented electrode system. In this embodiment the disadvantage of system as illustrated in FIG. 3 is addressed. The angle (θ) of the fragmented pieces (401a and 401b) are placed parallel to the central axis passing through the fragmented electrode system could vary anywhere between 0 and 360°. In a further preferred embodiment, the fragmented pieces (401b) are placed parallel with respect to one another are at an angle (θ) to the central axis passing through the fragmented electrode system, such that when an imaginary line dropped from the corner (iii) of the first fragmented piece of a the fragmented electrode system to the corner (viii) of the second fragmented piece of a the fragmented electrode system which is placed adjacent and parallel to the first fragmented piece of a the fragmented electrode system, the imaginary line is perpendicular to the central axis passing through the fragmented electrode system.

Typically, this provides maximum exposure of the processing material to the plasma.

Typically, inclined orientation, i.e., the formation of angle (θ) by the fragmented pieces to the central axis passing through the fragmented electrode system, allow development of peristaltic acceleration of the plasma in the direction of inclination.

In an embodiment of the invention, more than one electrodes may comprise of fragmented electrode system.

In an embodiment of the invention, the degree of inclination or value of (θ) formed by the fragmented pieces to the central axis passing through the fragmented electrode system may vary for each fragmented electrode system, wherein the system comprises of more than one fragmented electrode system.

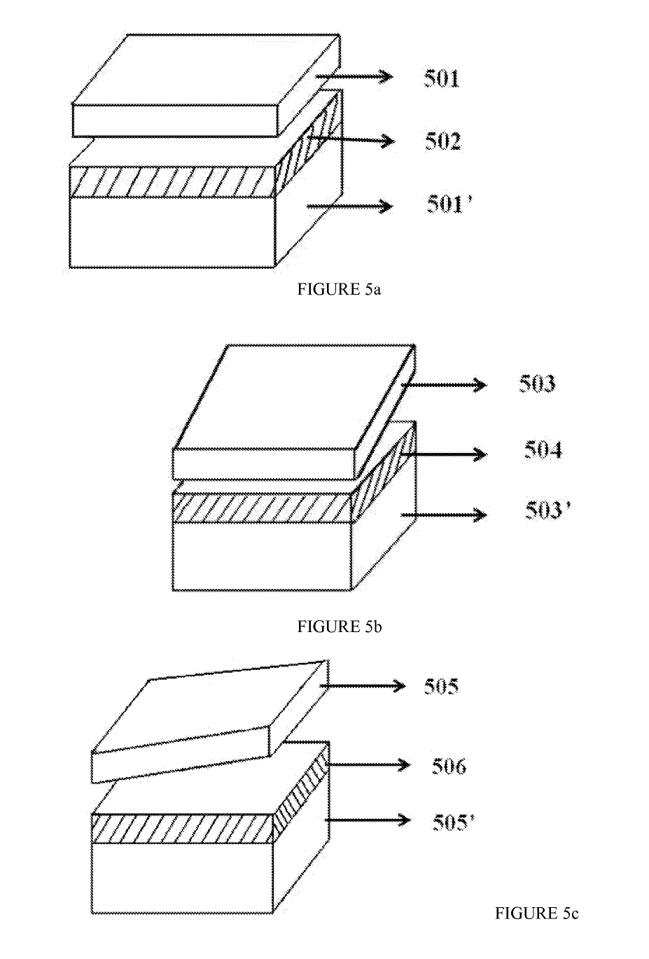

FIG. 5a through FIG. 5c are exemplary embodiments illustrating the isometric view of a pair of electrodes, wherein the views illustrate the various positions of at least one electrode with respect to another second electrode. In FIG. 5a the at least one electrode (501′) overlaid with at least one dielectric material (502) faces the another second electrode (501) which is parallel to the at least one electrode (501). In FIG. 5b the at least one electrode (503′) overlaid with at least one dielectric material (502) faces the another second electrode (503) which is diverging away from the at least one electrode (503′). In FIG. 5b the at least one electrode (505′) overlaid with at least one dielectric material (502) faces the another second electrode (505) which is tilted away from the at least one electrode (505′) wherein three sides and three corners of the another second electrode (505) is not parallel to that of at least one electrode (505′).

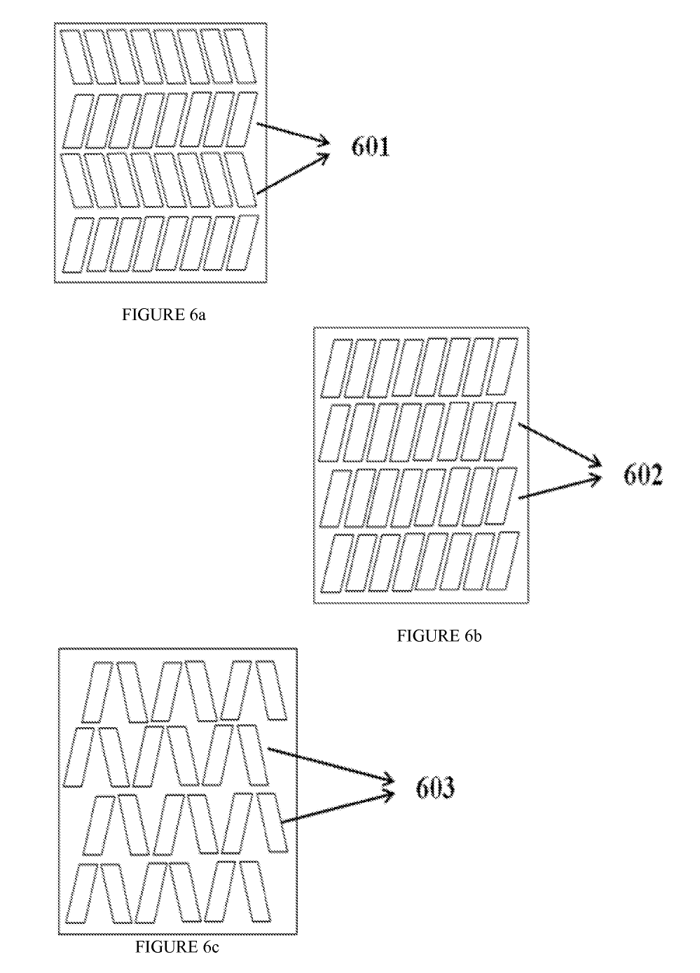

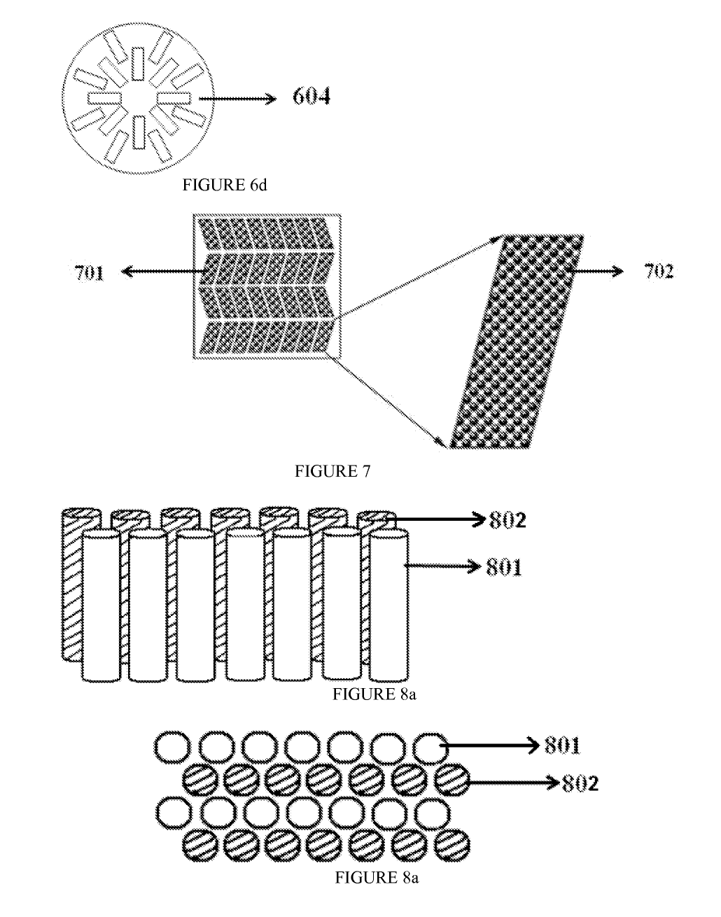

FIG. 6a through FIG. 6d are exemplary embodiments illustrating the arrangement of the fragmented pieces with respect to one another in a fragmented electrode system. FIG. 6a and FIG. 6b illustrates the arrangement of the fragmented pieces (601 and 602) with respect to one another in a fragmented electrode system, wherein the fragmented pieces (601 and 602) are arranged parallel to one another.

FIG. 6c illustrates the arrangement of the fragmented pieces (603) with respect to one another in a fragmented electrode system, wherein the adjacent fragmented pieces (603) are arranged in an alternate divergent and convergent configuration to one another.

FIG. 6d illustrates the arrangement of the fragmented pieces (604) with respect to one another in a fragmented electrode system, wherein the adjacent fragmented pieces (604) are arranged radially around the center of a circle.

FIG. 7 is an exemplary embodiment illustrating perforations on the fragmented pieces of a fragmented electrode system. The fragmented pieces (701) of the fragmented electrode system as illustrated in the FIG. 7 is magnified to illustrate the perforations (702) present on the surface of the fragmented pieces (701).

Typically, the perforations along the surface of the fragmented pieces of a fragmented electrode system may allow introduction process gas into the system i. e. the fragmented electrode system themselves acting like shower heads for the process gas.

Alternately or simultaneously, perforations may be present on the at least one dielectric material.

Alternately, perforations on the fragmented pieces of a fragmented electrode system may allow introduction of process gas into the system and perforations on the at least one dielectric material may collect the processed gas or vice versa.

Alternately, one set of perforations on the fragmented pieces of a fragmented electrode system or the at least one dielectric material may allow introduction of process gas and another second set of perforations on the fragmented pieces of a fragmented electrode system or the at least one dielectric material may collect the processed gas.

FIG. 8a and FIG. 8b are side and top views, respectively, of an exemplary embodiment illustrating tubular fragmented pieces of a fragmented electrode system. In this embodiment the fragmented pieces (801) of a fragmented electrode system are separated by at least one dielectric material (802) which is also tubular.

Typically, the arrangement of the tubular fragmented pieces of a fragmented electrode system and tubular structure of the at least one dielectric material as illustrated in FIG. 8a and FIG. 8b allow treatment of the processing material without being exposed to high voltages.

Typically, the arrangement of the tubular fragmented pieces of a fragmented electrode system and tubular structure of the at least one dielectric material as illustrated in FIG. 8a and FIG. 8b is used in conveyor belts which are used in applications such as but not limited to sterilization of eggs, medical devices.

Typically, the arrangement of the tubular fragmented pieces of a fragmented electrode system and tubular structure of the at least one dielectric material as illustrated in FIG. 8a and FIG. 8b allow the plasma generated from the system is channeled towards a processing material on a conveyor belt.

Typically, the arrangement of the tubular fragmented pieces of a fragmented electrode system and tubular structure of the at least one dielectric material as illustrated in FIG. 8a and FIG. 8b may have different orientations with respect to the processing material such as but not limited to vertically above, vertically below, inclined or sideways depending upon the field of application.

In an embodiment of the invention, introduction of steam along with plasma generation improves quality of sterilization.

Typically, hydroxyl radicals generated in steam along with plasma enhance the sterilization process.

In an embodiment of the invention, the at least one electrode and the another second electrode or the fragmented pieces of the fragmented electrode system may be subjected to different or varied frequencies to produce plasma.

Typically, the plasma produced due to application of different or varied frequencies to the at least one electrode and the another second electrode or the fragmented pieces of the fragmented electrode system is stable.

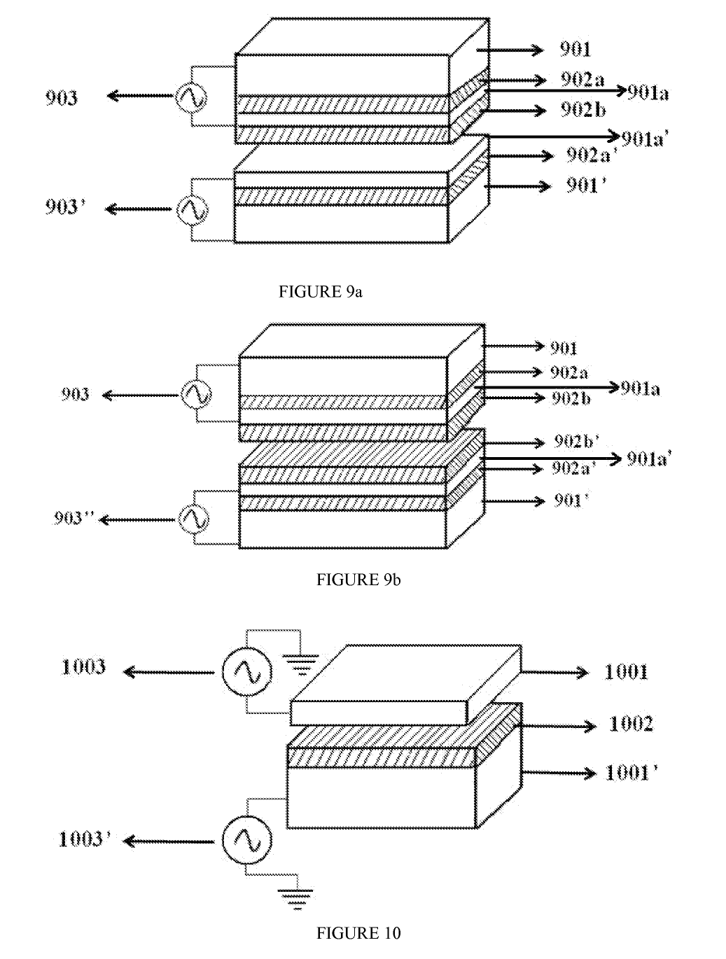

FIG. 9a and FIG. 9b are isometric views of exemplary embodiments illustrating the various configurations of the at least one electrode and the another second electrode or the fragmented pieces of the fragmented electrode system with respect to one another and with respect to the at least one dielectric material.

In FIG. 9a the fragmented pieces (901 and 901a) of the fragmented electrode system are placed alternately with dielectric material (902a and 902b). The fragmented pieces (901′ and 901a′) of the another second fragmented electrode system are placed on two sides of the at least one dielectric material 902a′. Different frequencies 903 and 903′ is applied to the fragmented pieces (901 and 901a) and fragmented pieces (901′ and 901a′) of the fragmented electrode systems, respectively.

In FIG. 9b the fragmented pieces (901 and 901a) of the fragmented electrode system are placed alternately with dielectric material (902a and 902b). The fragmented pieces (901′ and 901a′) of the another second fragmented electrode system are placed alternately with dielectric material (902a′ and 902b′). Different frequencies 903 and 903″ is applied to the fragmented pieces (901 and 901a) and fragmented pieces (901′ and 901a′) of the fragmented electrode systems, respectively.

Alternatively, in FIG. 9a and FIG. 9b gaps or distances may be left between the adjacent fragmented pieces of the fragmented electrode system and dielectric material.

In an embodiment of the invention, the thickness of the at least one dielectric material may vary according to places where plasma generation is less required than the other places where it is required more.

Typically, for coupling the different or varied frequencies are applied to the at least one electrode and the another second electrode or the fragmented pieces of the fragmented electrode system at intervals, after plasma has already been generated by the application of previous frequency.

FIG. 10 is the isometric views of an exemplary embodiment illustrating the another configuration for application of different or varied frequencies to the at least one electrode and the another second electrode or the fragmented pieces of the fragmented electrode system. In this arrangement different or varied frequencies (1003 and 1003′) is applied to electrodes (1001 and 1001′), wherein the electrodes separated by at least one dielectric material. Different or varied frequencies are applied with respect to the ground.

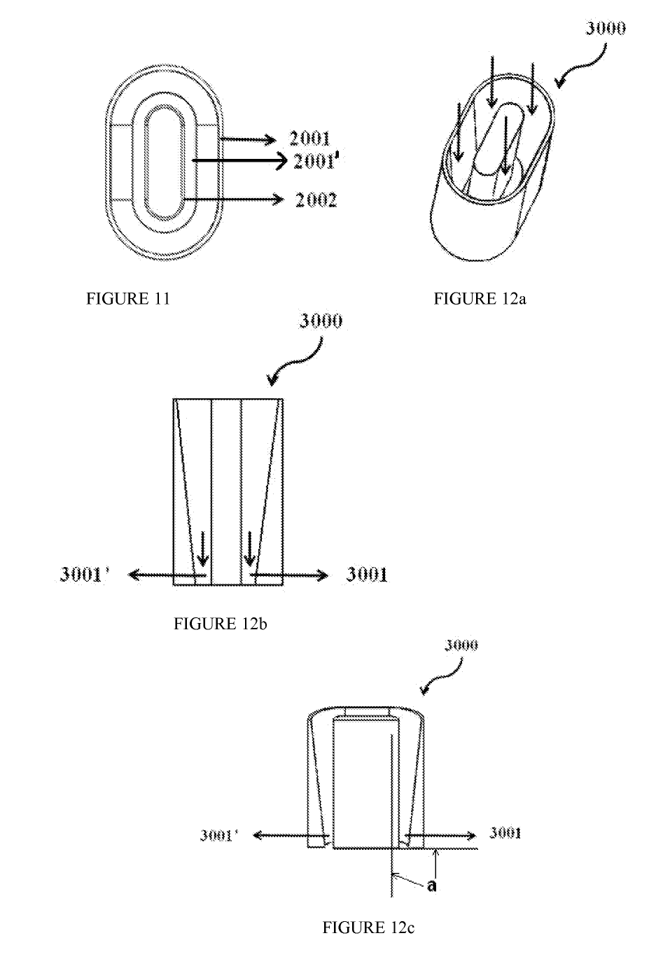

FIG. 11, FIG. 12a, FIG. 12b, FIG. 12c, FIG. 13a, FIG. 13b, and FIG. 13c illustrates various views of embodiments of systems for high pressure plasma discharge comprising at least two electrodes (2001 and 2002) having a concentric arrangement with respect to one another, wherein the at least two electrodes form a contraption (2001′) between the inner and the outer electrode; and wherein at least a portion of the inner or outer surface of at least one of the at least two electrodes tapers in at least one direction. FIG. 12a illustrates the tapering or inclined surfaces of the at least two electrodes aid in the peristaltic acceleration of process gas or plasma. The arrowheads illustrate the direction of movement of the peristaltic acceleration of process gas or plasma. FIG. 12b illustrates the inner surface of the outer electrode tapers inwards thereby narrowing contraption area of the system (3000) depicted by 3001 and 3001′. FIG. 12c illustrates the isometric view of the system (3000) with the inner surface of the outer electrode tapers inwards thereby narrowing contraption area depicted by 3001 and 3001′ which has been demonstrated against an imaginary line gauge (a) as can be viewed in the FIG. 12c. FIG. 13a illustrates the tapering or inclined surfaces of the at least two electrodes aid in the increase in E-field generation between the at least two electrodes. FIG. 13b illustrates the inner surface of the outer electrode (4002) tapers inwards and the outer surface of the inner electrode (4001) taper inwards of the system (4000). FIG. 13c illustrates the isometric view of the system (4000) in which the inner surface of the outer electrode (4002) tapers inwards and the outer surface of the inner electrode (4001) taper inwards of the system (4000) which has been demonstrated against an imaginary line gauge (b) as can be viewed in the FIG. 13c.

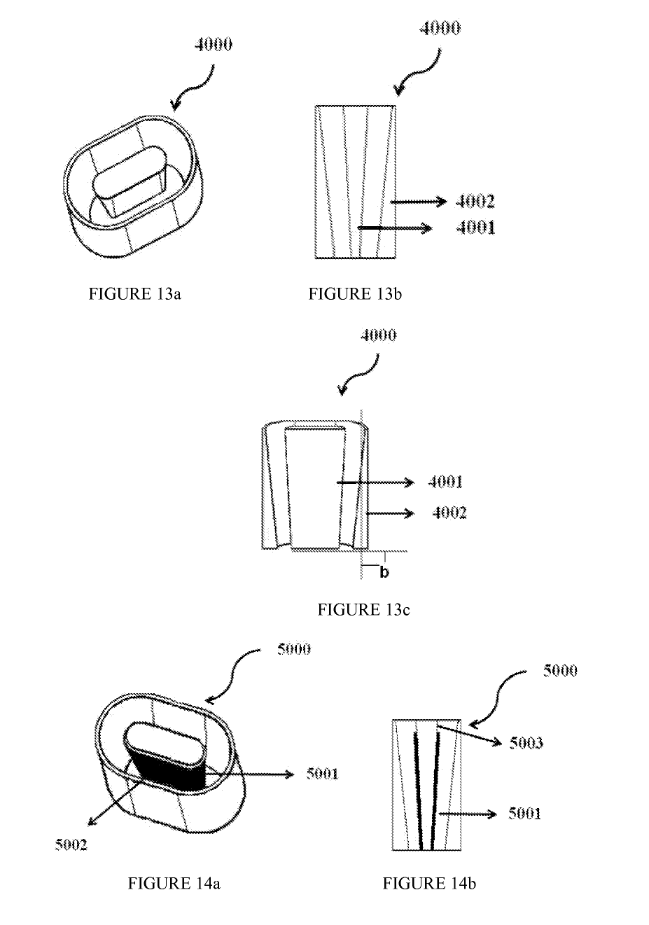

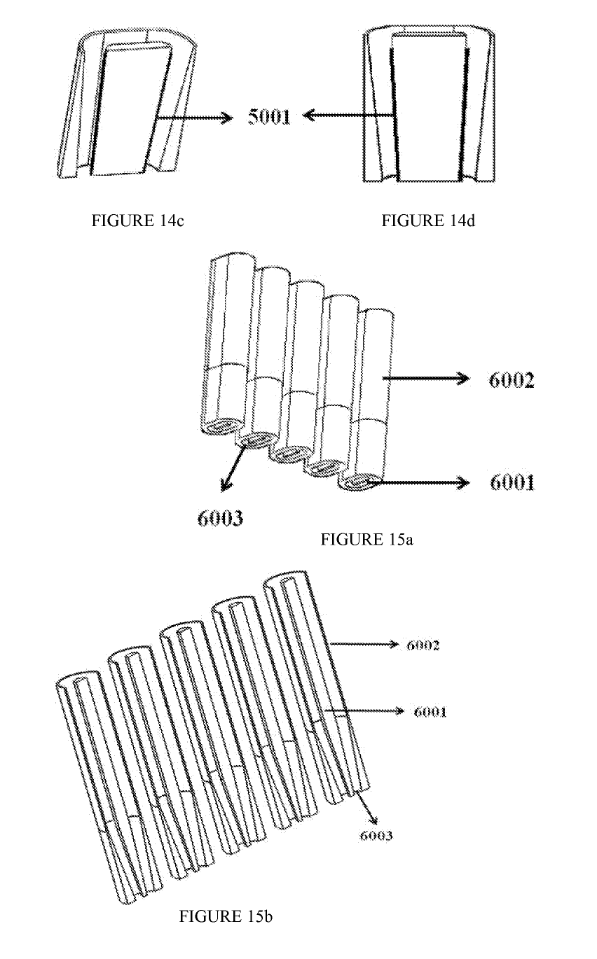

FIG. 14a through FIG. 14d illustrate various isometric views of an embodiment (5000) of the invention, wherein at least one dielectric material (5001) is placed between the at least two electrodes (5002 and 5003). The thickness of the at least one dielectric material (5001) and the extent to which the at least one dielectric material (5001) covers the at least two electrodes (5002 and 5003) may vary. The at least one dielectric material (5001) may be placed on the outer surface of the inner electrode or the inner surface of the outer electrode or both.

FIG. 15a and FIG. 15b illustrate various isometric views of exemplary embodiments illustrating the arrangement of an array of the at least two electrodes (6001 and 6002) which have a concentric arrangement with respect to one another, wherein the two electrodes form a contraption (6003) between the inner (6001) and the outer (6002) electrode. FIG. 15b illustrate the isometric view of the longitudinal cross-section of the at least two electrodes (6001 and 6002) which have a concentric arrangement with respect to one another, wherein the two electrodes form a contraption (6003) between the inner (6001) and the outer (6002) electrode.

In an embodiment of the invention, the at least two electrodes which have a concentric arrangement with respect to one another, wherein the two electrodes form a contraption between the inner and the outer electrode may form an array in various arrangements as suitable for an application.

In an embodiment of the invention, the at least two electrodes which have a concentric arrangement with respect to one another, wherein the two electrodes form a contraption between the inner and the outer electrode, may form an array wherein each of the at least two electrodes which have a concentric arrangement with respect to one another, wherein the two electrodes form a contraption between the inner and the outer electrode, may be oriented along the same plane or multiple planes or pointing towards same direction or multiple directions.

Typically, uniform plasma is generated along the opening of the contraption formed between the inner and the outer electrode of the at least two electrodes which have a concentric arrangement with respect to one another.

Alternatively, the at least two electrodes which have a concentric arrangement with respect to one another may be hollow structures to reduce the weight of the system.

In an embodiment of the invention, high pressure plasma discharge may be generated at a frequency range of 1 Hz to 100 GHz. More preferably, the frequency may be between 10 Hz and 100 Hz. Still further preferably frequency of operation is within the audible frequency range which is less than 20 kHz.

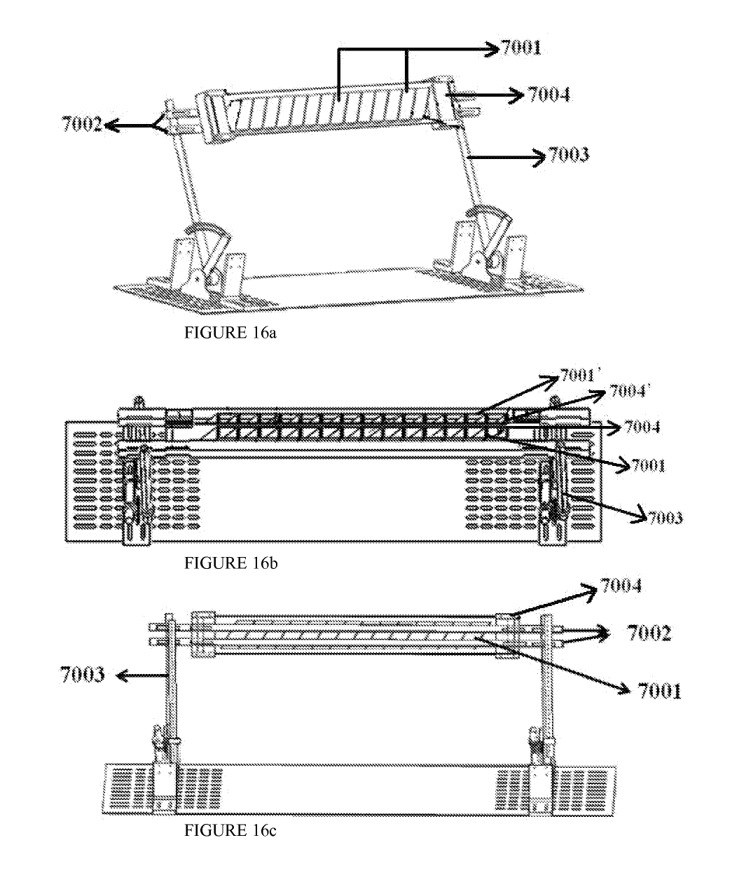

FIG. 16a, FIG. 16b, and FIG. 16c illustrate various isometric views of exemplary embodiments illustrating the arrangement of an array of fragmented pieces (7001) of a fragmented electrode system and at least one dielectric material (7004) placed parallel to the fragmented pieces of the fragmented electrode system. This arrangement is placed on an “L” shaped bracket (7003) with tubes to allow the arrangement described herein above to be held in any suitable position. Additional support elements (7002) may further be used to keep the at least one dielectric material in position (7004), i. e., parallel to the fragmented pieces (7001) of the fragmented electrode system. FIG. 16b illustrate a second array of fragmented pieces (7001′) of a fragmented electrode system and at least one dielectric material (7004′) placed parallel to the fragmented pieces (7001) of the fragmented electrode system, overlaying the array illustrated in FIG. 16a. The overlaying array faces the fragmented electrode system of FIG. 16a such that the at least one dielectric material (7004) of FIG. 16a faces the at least one dielectric material (7004′) of the second array of the second fragmented electrode system. FIG. 16c is the front view of the arrangement of two arrays of fragmented pieces (7001 and 7001′) of fragmented electrode systems and at least one dielectric material (7004 and 7004′) placed such that the dielectric material (7004) of one fragmented electrode system faces the dielectric material (7004′) of the second fragmented electrode system.

FIG. 17 illustrate isometric views of ‘couplers’ to hold tubes of FIG. 16a, FIG. 16b, and FIG. 16c at any orientation. Nuts and bolts may be used to secure the couplers in any suitable orientation. The couplers shown in FIG. 17 allow any orientation of the fragmented electrode system which is mounted on the tubes of the “L” bracket. This allows the system of the present invention fit into any existing machine's fabric feed. This would reduce the necessity of making new provisions to suit this system as described in the invention.

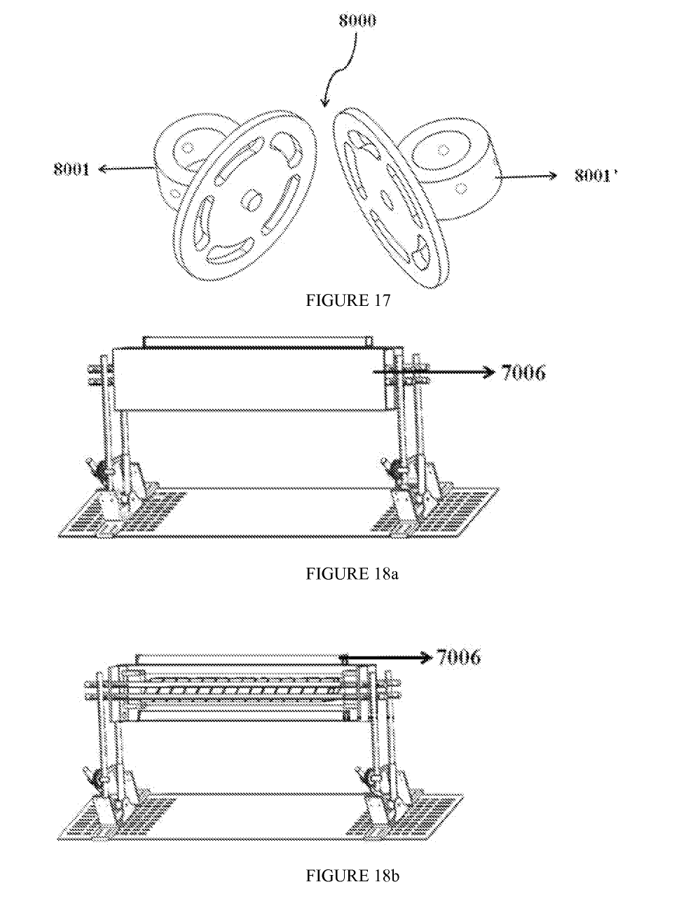

FIG. 18a and FIG. 18b illustrate isometric views of exemplary embodiments illustrating the array such as that described FIG. 16a, FIG. 16b, and FIG. 16c enclosed in a containment chamber. The containment chamber (7006) allows a suitable environment to be generated and maintained for operation of the systems in accordance with the present invention.

In an embodiment of the invention, the containment chamber in accordance with the invention is additionally, optionally, simultaneously, or concurrently, made up of variety of material such as but not limited to conducting; non conducting; or partially or semi conducting material or any combination thereof

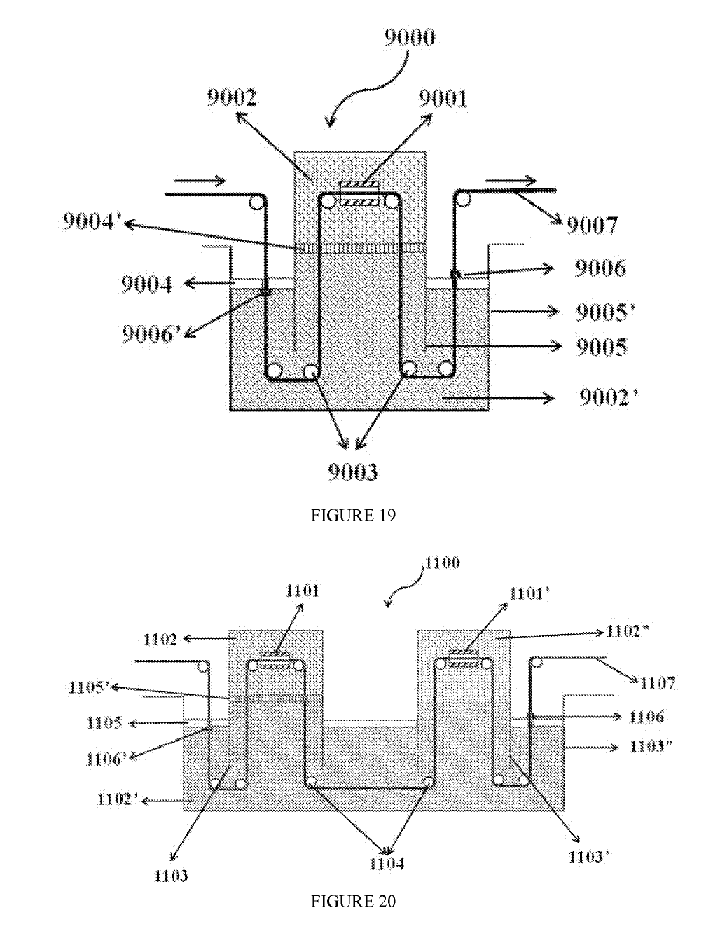

FIG. 19 illustrate an exemplary embodiment illustrating a fragmented electrode system (9001) is placed within a gas container (9005) containing a gas with lower molecular weight (9002) than the gas contained in another gas container (9005′) containing a gas with higher molecular weight (9002′), wherein the gas container (9005′) containing a gas with lower molecular weight (9002) is placed within the gas contained in another gas container (9005′) containing a gas with higher molecular weight (9002′). Low molecular weight gas (9002) shall always remain in the top region of the gas container (9005) containing a gas with lower molecular weight, and the plasma once started in this region containing will work indefinitely without the necessity of much replenishment of the said gas. This usually results in large savings. The “processed gas” is usually heavier than the low molecular weight gas (9002) and hence diffuses downwards. Vents (9004′) provided in the gas barrier of the gas container (9005) containing the gas with lower molecular weight (9002) allows the “processed gas” to move downwards.

For the purpose of this invention, a gas as mentioned hereinabove may be replaced by any suitable fluid such as but not limited to liquids, mixture of gases, plasmas, semi solids, colloids, colloidal aerosols, colloidal emulsions, colloidal foams, colloidal dispersions, or hydrosols, suspension, aerosol, emulsions, solutions, or any combinations thereof.

In an embodiment of the invention, the vents may optionally be present to prevent turbulent mixing between the two gases with vastly different molecular weights. These vents may be further connected to an external unit to separate the accumulated “processed gas” over a period of time. Those skilled in the art can design and build such units.

Typically, flaps, optionally made of flexible or inflexible material such as but not limited to rubber, are placed to hold the fabric or a “processed gas” in place. These flaps prevent atmospheric gases from entering and mixing with the gases within the said gas containers (9005, 9005′) or process gas from leaving the system.

In an embodiment of the invention, more than two gases may be used in the gas containers. Furthermore, more than one gas may also be used in a single container. Those skilled in the art can design such units.

FIG. 20 illustrate an exemplary embodiment illustrating two fragmented electrode system (1101, 1101′) is placed within two gas container (1103, 1103′) containing gases with lower molecular weights (1102, 1102″) than the gas contained in another gas container (1103″) containing a gas with higher molecular weight (1102′), wherein the gas container (1103″) containing gases with lower molecular weight (1102, 1102″) is placed within the gas contained in another gas container (1103″) containing a gas with higher molecular weight (1102′). Low molecular weight gas (1102, 1102″) shall always remain in the top region of the gas container (1103, 1103′) containing a gas with lower molecular weight (1102, 1102″), and the plasma once started in this region containing will work indefinitely without the necessity of much replenishment of the said gas. This usually results in large savings. The “processed gas” is usually heavier than the low molecular weight gas (1102, 1102″) and hence diffuses downwards. Vent provided in the gas barrier (1105′) of the gas container (1103) containing the gas with lower molecular weight (1102) allows the “processed gas” to move downwards.

In an embodiment of the invention, the components of the present invention may be connected or arranged by using any suitable method and may include without limitation use of one or more of welding, adhesives, riveting, fastening devices such as but not limited to screw, nut, bolt, hook, clamp, clip, buckle, nail, pin, ring.

Furthermore, this invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures. It will be understood that when an element is referred to as being “connected” or “coupled” or “attached” or “fixed” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “or” includes any and all combinations of one or more of the associated listed items.

The terminology used herein is for the purpose of describing particular embodiments only and is not intended to be limiting the invention. As used herein, the singular forms “a”, “an” and “the” are intended to include the plural forms as well, unless the context clearly indicates otherwise. It will be further understood that the terms “comprises” or “comprising,” when used in this specification, specify the presence of stated features, integers, steps, operations, elements, or components, but do not preclude or rule out the presence or addition of one or more other features, integers, steps, operations, elements, components, or groups thereof.

The process steps, method steps, protocols, algorithms or the like may be described in a sequential order, such processes, methods, protocol and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously, in parallel, or concurrently.

In addition to the embodiments and examples shown, numerous variants are possible, which may be obvious to a person skilled in the art relating to the aspects of the invention.

In an embodiment of the invention, the component or the parts of the system may be coated, painted or colored with a suitable chemical to retain or improve its properties, or to improve the aesthetics or appearance.

In an embodiment of the invention, the component or the parts of the system may be consumed partially or wholly during the processing. Such components may provide material for polymerizing, chemically activating, etching or depositing material on the substrate.

The aim of this specification is to describe the invention without limiting the invention to any one embodiment or specific collection of features. Person skilled in the relevant art may realize the variations from the specific embodiments that will nonetheless fall within the scope of the invention.

It may be appreciated that various other modifications and changes may be made to the embodiment described without departing from the spirit and scope of the invention.

### LIST OF REFERENCES

K. G. Donohoe, PhD Thesis, California Institute of Technology, Pasadena, Calif. (1976).
S. Kanazawa, M. Kogoma, T. Moriwaki, S. Okazaki, 8th International Symposium on Plasma Chemistry, Tokyo (1987) 1839-1844.
S. Kanazawa, M. Kogoma, T. Moriwaki, S. Okazaki, J. Phys. D: Appl. Phys. 21 (1988) 838-840.
S. Okazaki, M. Kogoma, M. Uehara, Y. Kimura, J. Phys. D: Appl. Phys. 26 (1993) 889-892.
F. Massines, C. Mayoux, R. Messaoudi, A. Rabehi, P. Ségur, Int. Conf. on Gas Discharges and their Applications, Swansea, UK (1992) 730-733.
F. Massines, A. Rabehi, P. Decomps, R. B. Gadri, P. Ségur, C. Mayoux, J. Appl. Phys. 83 (1998) 2950-2957
J. R. Roth, P. P. Tsai, L. C. Wadsworth, U.S. Pat. No. 5,403,453 of Apr. 4, 1995
A. V. Engel, R. Seeliger, M. Steenbeck, Z. Physik 85 (1933) 144-160
W. A. Gambling, H. Edels, Brit. J. Appl. Phys. 7 (1956) 376-379
A. J. Palmer, Appl. Phys. Lett. 25 (1974) 138-140
J. I. Levatter, S. Lin, J. Appl. Phys. 51 (1980) 210-222
N. Brenning, I. Axnäs, J. O. Nilsson, J. E. Eninger, IEEE Trans. Plama Sci. 25 (1997) 83-88
J. Tepper, M. Lindmayer, J. Salge, HAKONE VI, Cork, Ireland (1998) 123-127

I claim:

1. System for high pressure plasma discharge, wherein a system comprises,
a) at least one electrode which is fragmented into pieces and arranged to form a fragmented electrode system; and
b) at least one dielectric material placed between or parallel to the at least one electrode and another second electrode or fragmented pieces of the fragmented electrode systems, wherein the at least one electrode or fragmented pieces of the fragmented electrode system may have same or opposite charge;
wherein the pieces of the electrode which is fragmented can be arranged, parallel or divergent or convergent to one another and are at an angle to each other or the central axis passing through the electrode.

2. System for high pressure plasma discharge, as claimed in claim 1, wherein the said high pressure is, above or below or equal to the atmospheric pressure.

3. System for high pressure plasma discharge, as claimed in claim 1, wherein the another second electrode is an electrode which is unfragmented.

4. System for high pressure plasma discharge, as claimed in claim 1, wherein the fragmented pieces of the fragmented electrode system is, is at an angle between 0 and 360° to each other or the axis passing through the fragmented electrode system.

5. System for high pressure plasma discharge, as claimed in claim 1, wherein the at least one electrode or the fragmented pieces of the fragmented electrode system are of various shapes selected from a group consisting of taper, curved, flat, tubular, circular, elliptical, rectangular, square, polygonal, and any combination thereof.

6. System for high pressure plasma discharge, as claimed in claim 1, wherein the at least one electrode and the another second electrode or the fragmented pieces of the fragmented electrode system is arranged in at least one plane.

7. System for high pressure plasma discharge, as claimed in claim 1, wherein space or gap between the at least one electrode and the another second electrode or fragmented pieces of the fragmented electrode system varies concurrently or independently.

8. System for high pressure plasma discharge, as claimed in claim 1, wherein at least one electrode or fragmented piece of a fragmented electrode system or the dielectric or any combination thereof contain one or more perforation(s) along the surface, through which process gases may be introduced or collected.

9. System for high pressure plasma discharge, as claimed in claim 1, wherein the process gas introduced is selected from a group consisting of air, organic gas, inorganic gas, helium, neon, argon, xenon, noble gases, suspended particles, droplets of fluids, and any combination thereof.

10. System for high pressure plasma discharge, as claimed in claim 1, wherein the at least one dielectric material is placed midway between or closer to the at least one electrode or the another second electrode or the fragmented electrode system.

11. System for high pressure plasma discharge, as claimed in claim 1, wherein the at least one dielectric material has surface contours selected from a group consisting of smooth, regular, irregular, grained, wavy, serrated, wedged, teethed, and any combination thereof.

12. System for high pressure plasma discharge, as claimed in claim 1, wherein the at least one dielectric material is selected from a group consisting of solid, liquid semisolid, gaseous, and any combinations thereof.

13. System for high pressure plasma discharge, as claimed in claim 1, wherein the at least one electrode or the fragmented pieces of the fragmented electrode system has polygonal cross-sectional shape, wherein the polygon comprises ‘n’ sides, where is defined as n=3 (corresponding to a triangle) to infinity (corresponding to a circle).

14. System for high pressure plasma discharge, as claimed in claim 1, wherein the at least one electrode or the fragmented pieces of the fragmented electrode system is flat.

15. System for high pressure plasma discharge, as claimed in claim 1, wherein the at least one electrode or the fragmented pieces of the fragmented electrode system is curved inwards or outwards.

16. System for high pressure plasma discharge, as claimed in claim 1, wherein the at least one electrode or the fragmented pieces of the fragmented electrode system is at least partially hollow or partially solid.

17. System for high pressure plasma discharge, as claimed in claim 1, is cooled by a cooling agent.

18. System for high pressure discharge, as claimed in claim 1, wherein at least one fragmented electrode system, wherein the pieces of the electrodes are stacked on one another, is placed in at least a gas, wherein the gas remains separated from at least a second gas, and wherein the at least one gas or the at least a second gas does not require to be replenish.

19. Methods for high pressure plasma discharge, method comprising the steps of,
a) arranging fragmented pieces of at least one electrode to form a fragmented electrode system; and
b) placing at least one dielectric material between or parallel to the at least one electrode and another second electrode or fragmented pieces of the fragmented electrode systems;
wherein the pieces of the electrode which is fragmented is arranged parallel or divergent or convergent to one another and are at an angle to each other or the central axis passing through the electrode.

20. System for high pressure plasma discharge, wherein a system comprises,
a) at least two electrodes which have a concentric arrangement with respect to one another, wherein the two electrodes form a contraption between the inner and the outer electrode; and
b) at least one dielectric material placed between or parallel to the at least one electrode and another second electrode or fragmented pieces of the fragmented electrode systems, wherein the said electrodes or fragmented electrode systems may have same or opposite charge;
wherein the inner or outer surface of at least one of the electrodes tapers in at least one direction.

21. Methods for high pressure plasma discharge, method comprising the steps of,
a) arranging at least two electrodes in a concentric arrangement with respect to one another such that the at least two electrodes form a contraption between the inner and the outer electrode; and
b) placing at least one dielectric material between or parallel to the at least one electrode and another second electrode or fragmented pieces of the fragmented electrode systems;
wherein the inner or outer surface of at least one of the electrodes tapers in at least one direction.
